(19) United States
(12) Patent Application Publication
(10) Pub. No.: US 2014/0291754 A1
(43) Pub. Date: Oct. 2, 2014

(54) SEMICONDUCTOR STRUCTURE HAVING BURIED WORD LINE AND METHOD OF MANUFACTURING THE SAME

(71) Applicant: INOTERA MEMORIES, INC., TAOYUAN COUNTY (TW)

(72) Inventors: TZUNG-HAN LEE, TAIPEI CITY (TW); YAW-WEN HU, TAOYUAN COUNTY (TW)

(21) Appl. No.: 13/920,269

(22) Filed: Jun. 18, 2013

(30) Foreign Application Priority Data
Apr. 1, 2013 (TW) 102111661

(51) Int. Cl. H01L 29/78; H01L 29/66

(52) U.S. Cl. CPC H01L 29/7827; H01L 29/66666
USPC 257/330; 438/589

(57) ABSTRACT

A semiconductor structure having buried word line formed in a trench in a semiconductor substrate includes a gate oxide layer, a gate conductor, a gate cap layer, a blocking layer, and an isolation structure. The gate oxide layer is formed on the inner surface of the trench, the gate conductor is formed in the trench, and the gate cap layer is formed on the gate conductor. The blocking layer surrounds a bottom portion of the gate conductor, and the bottom portion of the gate conductor is isolated from the gate oxide layer by the blocking layer. The isolation structure surrounds a top portion of the gate conductor and in contact with the top end of the blocking layer. The top portion of the gate conductor is isolated from the gate oxide layer and the from the gate cap layer by the isolation structure.

### BACKGROUND

1. Field of the Invention

The instant disclosure relates to a semiconductor device and method of manufacturing the same; in particular, to a semiconductor structure having buried word line and method of manufacturing the same.

2. Description of Related Art

The dynamic random access memory (DRAM) is one of the common the semiconductor memory devices. Dynamic random access memory is a data storage device for storing data as capacitor charges. Each memory unit cell of the dynamic random access memory can have a storage capacitor and a transistor, and the charges can be transferred therebetween. Each memory cell can utilize a word line for addressing and can utilize a bit line for accessing the data. As electronic products become increasingly light, thin, short, and small, dynamic random access memory device must also meet the requirements of high-density design and miniaturization.

### SUMMARY OF THE INVENTION

The object of the instant disclosure is to provide a semiconductor structure having buried word line and a method of manufacturing the same and utilize an isolation structure surrounding a top portion of a gate conductor to isolate the top portion of the gate conductor from a gate oxide layer and from a gate cap layer. In addition, the isolation structure is in contact with a top end of a blocking layer. Hence, the blocking layer and the isolation structure can block the ingredients of the gate conductor from diffusing into the gate oxide layer or the gate cap layer.

According to one exemplary embodiment of the instant disclosure, a semiconductor structure having buried word line is provided, which is formed in a trench in a semiconductor substrate. The semiconductor structure having buried word line includes a gate oxide layer, a gate conductor, a gate cap layer, a blocking layer, and an isolation structure. The gate oxide layer is formed on the inner surface of the trench, the gate conductor is formed in the trench, and the gate cap layer is formed on the gate conductor. The blocking layer surrounds a bottom portion of the gate conductor, and the bottom portion of the gate conductor is isolated from the gate oxide layer by the blocking layer. The isolation structure surrounds a top portion of the gate conductor and in contact with the top end of the blocking layer. The top portion of the gate conductor is isolated from the gate oxide layer and the from the gate cap layer by the isolation structure.

According to one exemplary embodiment of the instant disclosure, a method of manufacturing a semiconductor structure having buried word line is provided, which includes steps of: firstly, a semiconductor substrate having a trench is provided. A gate oxide layer is formed on the inner surface of the trench. Subsequently, a blocking layer is formed in the trench and at the bottom of the trench, and the blocking layer being disposed on the gate oxide layer. A gate conductor is then formed in the trench, the blocking layer surrounding a bottom portion of the gate conductor, and the bottom portion of the gate conductor being isolated from the gate oxide layer by the blocking layer. Subsequently, an isolation material is deposited for covering the inner surface of the trench and for covering a top portion of the gate conductor, and in contact with the top end of the blocking layer. A gate cap material is then deposited for covering the isolation material. Finally, a portion of the isolation material and a portion of the gate cap material on the surface of the semiconductor substrate are removed for forming an isolation structure and a gate cap layer, and the top portion of the gate conductor being isolated from the gate oxide layer and the gate cap layer by the isolation structure.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1A illustrates a cross-sectional view of a semiconductor structure having buried word line in accordance with an embodiment of the instant disclosure;

FIG. 1B illustrates a perspective view of a semiconductor structure having buried word line in accordance with FIG. 1A;

FIGS. 2A to 2E are cross-sectional views of a method of manufacturing a semiconductor structure having buried word line in accordance with an embodiment of the instant disclosure; and

FIG. 3 is a flow chart of a method of manufacturing a semiconductor structure having buried word line in accordance with another embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

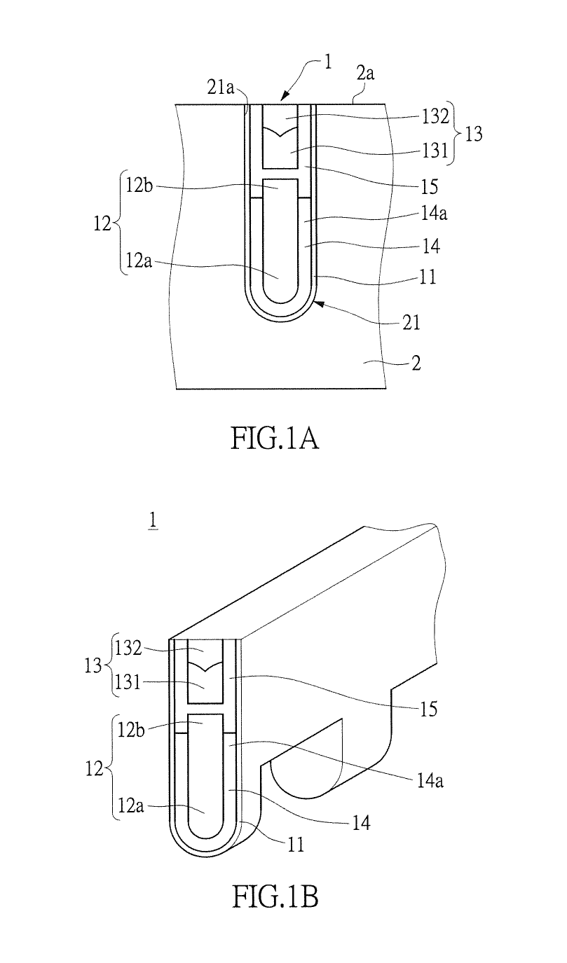

Referring to FIGS. 1A and 1B. FIG. 1A illustrates a cross-sectional view of a semiconductor structure having buried word line in accordance with an embodiment of the instant disclosure. FIG. 1B illustrates a perspective view of a semiconductor structure having buried word line in accordance with FIG. 1A. The semiconductor structure 1 having buried word line is formed in a trench 21 in a semiconductor substrate 2. The semiconductor structure 1 having buried word line includes a gate oxide layer 11, a gate conductor 12, a gate cap layer 13, a blocking layer 14, and an isolation structure 15.

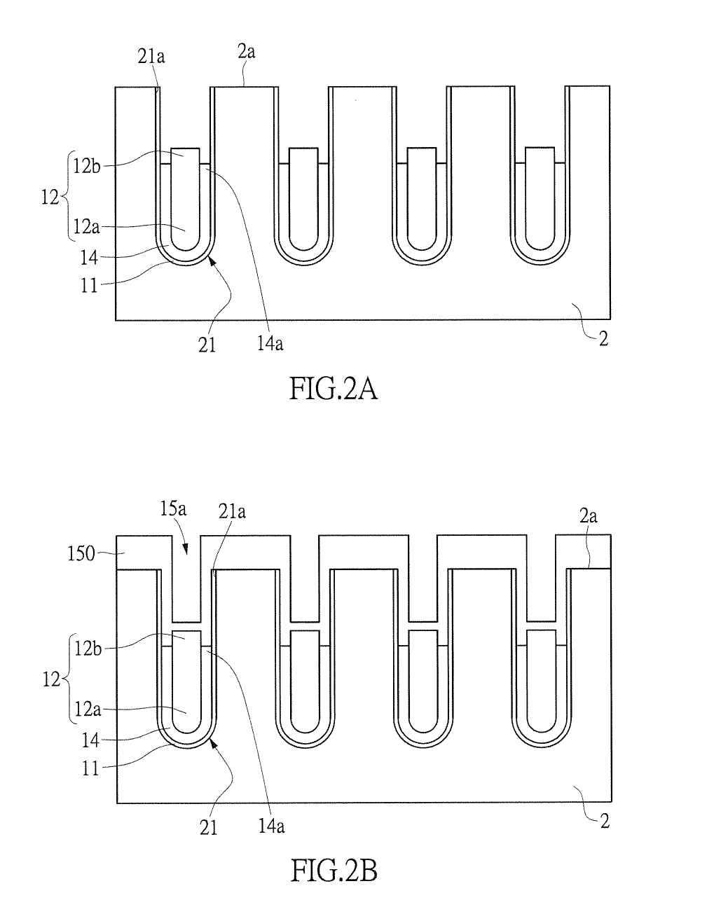

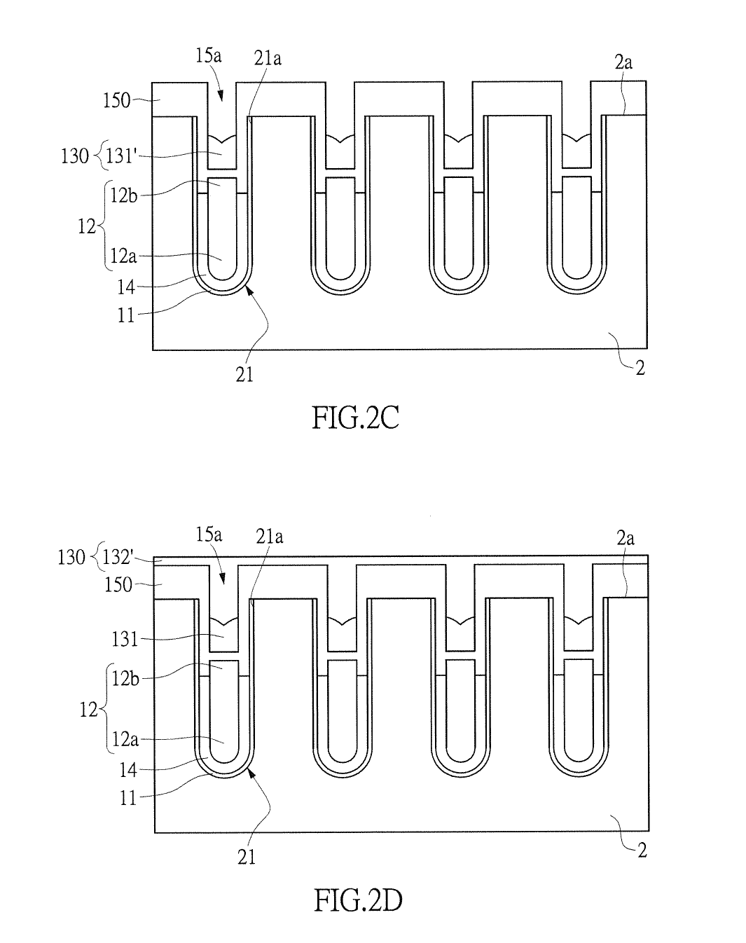

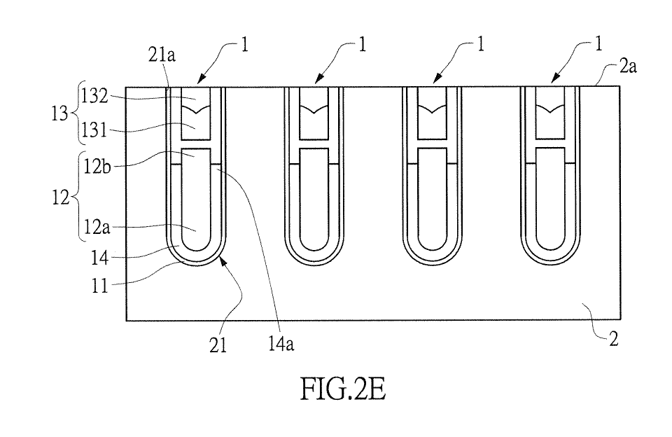

Please refer to FIGS. 2A to 2E. FIGS. 2A and 2E are cross-sectional views of a method of manufacturing a semiconductor structure having buried word line in accordance with an embodiment of the instant disclosure. Firstly, a semiconductor substrate 2 is provided, and the semiconductor substrate 2 has a trench 21 formed therein. The semiconductor substrate 2 may have a plurality of active areas arranged in columns and rows. Specifically, a plurality of shallow trench isolations can be formed in the semiconductor substrate 2 to define the active areas. In an exemplary embodiment, the semiconductor substrate 2 may include semiconductor structure having a semiconductor surface, such as substrates including undoped or doped silicon wafer. In addition, the semiconductor substrate 2 may have a memory array region and a peripheral circuit area. In order to simplify the explanation, the description hereinafter exemplarily illustrates the details in the memory array region only for the purpose of further explaining the scope of the instant disclosure.

As shown in FIG. 2A, the semiconductor substrate 2 has the trench 21 formed therein. In the instant disclosure, the trench 21 can be formed within the semiconductor substrate 2 by etching process carried out in the active areas of the semiconductor substrate 2. To put it concretely, a hard mask layer can be deposited on the surface 2a of the semiconductor substrate 2. For example, the hard mask layer can be formed on the surface 2a of the semiconductor substrate 2 by chemical vapor deposition process, and the hard mask layer can be patterned. The etching process is then carried out with the patterned hard mask layer as etching mask to remove part of the semiconductor substrate to form the trench 21 in the semiconductor substrate 2.

Subsequently, the gate oxide layer 11 is formed on the inner surface 21a of the trench 21. In the instant embodiment, the gate oxide layer 11 can be used as a dielectric layer. The gate oxide layer 11 can be a silicon oxide layer and formed by oxidation of portion of the semiconductor substrate adjacent to the inner surface 21a of the trench 21. In addition, a portion of the semiconductor substrate around the gate oxide layer 12 can be used as a gate channel.

Next, the blocking layer 14 is formed in the trench 21 and at the bottom of the trench 21, and the blocking layer 14 is disposed on the gate oxide layer 11. As shown in the FIGS. 1B and 2A in the instant embodiment, a cross section of the gate oxide layer 11 is U-shaped, and the gate oxide layer 11 defines a recess, which has a U-shaped cross section also. The blocking layer 14 is disposed in the recess. Etching process may be carried out after filling the recess with a blocking layer material by deposition, thereby forming the blocking layer 14 which has a U-shaped cross section. Hence, the blocking layer 14 has a recess, in which the gate conductor 12 can be disposed. For example, the blocking layer 14 can be a titanium nitride layer.

Then, the gate conductor 12 is formed in the trench 21, and the blocking layer 14 surrounds a bottom portion 12b of the gate conductor 12. Consequently, the bottom portion 12b of the gate conductor 12 is isolated from the gate oxide layer 11 by the blocking layer 14. To put it concretely, the trench 21 having the gate oxide layer 11 and the blocking layer 14 formed therein can be filled with a gate conductor material firstly, and then by removing part of the gate conductor material, in which the surface of the gate conductor material is below the surface 2a of the semiconductor substrate 2, so as to form the gate conductor 12 in the trench 21. For example, the gate conductor material may be deposited in the trench 21 to fill the trench 21, and part of the gate conductor material deposited in the trench 21 can be removed by etching back process. It is worth mentioned that the blocking layer 14 can surround the bottom portion 12b of the gate conductor 12, thereby the bottom portion 12b of the gate conductor 12 being isolated from the gate oxide layer 11 by the blocking layer 14. In the instant disclosure, the gate conductor 12 may contain tungsten.

Please refer to FIG. 2B, subsequently, an isolation material 150 is deposited for covering the inner surface 21 a of the trench and for covering a top portion 12a of the gate conductor 12, and the isolation material 150 is in contact with the top end 14a of the blocking layer 14. Specifically, as shown in FIG. 2B, a continuous layer of the isolation material 150 may be deposited on the semiconductor substrate 2 to cover the inner surface 21 a of the trench 21 and the top portion 12a of the gate conductor 12 and to reach the top end 14a of the blocking layer 14. That is, the isolation material 150 can conformingly cover the trench 21 of the semiconductor substrate 2, the top portion 12a of the gate conductor 12, and the top end 14a of the blocking layer 14 to be in contact with the top end 14a of the blocking layer 14. As a result, the top portion 12a of the gate conductor 12 is surrounded by the isolation material 150 and the blocking layer 14. In the instant disclosure, the surface of the top portion 12a of the gate conductor 12 is above the top end 14a of the blocking layer 14. The isolation material 150 may contain silicon (SiN) nitride or aluminum oxide (Al2O3).

Attention is now invited to FIGS. 2C and 2D. A gate cap material 130 is then deposited to cover the isolation material 150. The gate cap material 130 may contain dielectric material such as silicon nitride, silicon oxide or the like. In the instant embodiment, the gate cap layer 13 includes a first cap layer 131 and a second cap layer 132, and the second cap layer 132 is disposed on the first cap layer 131. To put it concretely, as shown in FIG. 2C, the isolation material 150 may have at least one opening 15a, and a first cap material 131′ can be deposited into the opening 15a to form the first cap layer 131. The first cap layer 131, for example, can be a TEOS oxide layer (tetraethylorthosilicate oxide layer). Next, as shown in FIG. 2D, a second cap material 132′ can be deposited to cover the isolation material 150 and the first cap layer 131. The second cap material 132′, for example, can be a HDP (high-density-plasma) layer.

Please refer to FIG. 2E. Finally, a portion of the isolation material 150 on the surface 2a of the semiconductor substrate 2 and a portion of the gate cap material 130 on the surface 2a of the semiconductor substrate 2 are removed to form the gate cap layer 13 and the isolation structure 15. In the instant embodiment, the isolation material 150 and the second cap material 132′ on the surface 2a of the semiconductor substrate 2 can be selectively removed by planarization process such as CMP process (chemical mechanical polishing process) to form the gate cap layer 13 and the isolation structure 15. It is worth mentioned that a cross section of the isolation structure 15 is H-shaped, and the top portion 12a of the gate conductor 12 is isolated from the gate oxide layer 11 and the gate cap layer 13 by the isolation structure 15.

In summary, as shown in FIGS. 1A and 1B, the semiconductor structure 1 having buried word line in accordance with the first embodiment of the instant disclosure is formed in the trench 21 in the semiconductor substrate 2. The semiconductor structure 1 having buried word line includes the gate oxide layer 11, the gate conductor 12, the gate cap layer 13, the blocking layer 14, and the isolation structure 15. The gate oxide layer 11 is formed on the inner surface 21a of the trench 21, the gate conductor 12 is formed in the trench 21, and the gate cap layer 13 is formed on the gate conductor 12. The blocking layer 14 surrounds the bottom portion 12b of the gate conductor 12, and the bottom portion 12b of the gate conductor 12 is isolated from the gate oxide layer 11 by the blocking layer 14. The isolation structure 15 surrounds the top portion 12a of the gate conductor 12 and in contact with the top end 14a of the blocking layer 14. The top portion 12a of the gate conductor 12 is isolated from the gate oxide layer 11 and the from the gate cap layer 13 by the isolation structure 15.

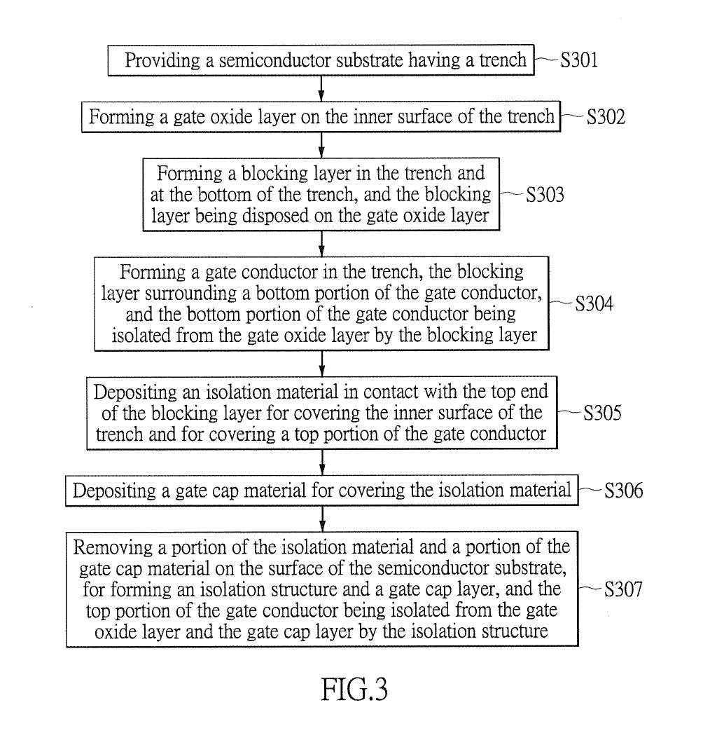

Please refer to FIG. 3. FIG. 3 is a flow chart of a method of manufacturing a semiconductor structure having buried word line in accordance with another embodiment of the instant disclosure. The embodiment of the instant disclosure includes the steps of:

Step S301: providing a semiconductor substrate 2 having a trench 21.

Step S302: forming a gate oxide layer 11 on the inner surface 21a of the trench 21.

Step S303: forming a blocking layer 14 in the trench 21 and at the bottom of the trench 21, and the blocking layer 14 being disposed on the gate oxide layer 11.

Step S304: forming a gate conductor 12 in the trench 21, the blocking layer 14 surrounding a bottom portion 12b of the gate conductor 12, and the bottom portion 12b of the gate conductor 12 being isolated from the gate oxide layer 11 by the blocking layer 14.

Step S305: depositing an isolation material 150 in contact with the top end 14a of the blocking layer 14 for covering the inner surface 21a of the trench 21 and for covering a top portion 12a of the gate conductor 12.

Step S306: depositing a gate cap material 130 for covering the isolation material 150.

Step S307: removing a portion of the isolation material 150 and a portion of the gate cap material 130 on the surface 2a of the semiconductor substrate 2, for forming an isolation structure 15 and a gate cap layer 13, and the top portion 12a of the gate conductor 12 being isolated from the gate oxide layer 11 and the gate cap layer 13 by the isolation structure 15.

According to the embodiment, the semiconductor structure 1 having buried word line and the method of manufacturing the same utilize the blocking layer 14 surrounding the bottom portion 12b of the gate conductor 12 to isolate the bottom portion 12b of the gate conductor 12 from the gate oxide layer 11. The semiconductor structure 1 having buried word line and the method of manufacturing the same in the embodiment utilize the isolation structure 15 surrounding the top portion 12a of the gate conductor 12 to isolate the top portion 12a of the gate conductor 12 from the gate oxide layer 11 and from the gate cap layer 13. In addition, the isolation structure 15 is in contact with the top end 14a of the blocking layer 14. Hence, the blocking layer 14 and the isolation structure 15 can block the ingredients of the gate conductor 12 from diffusing into the gate oxide layer 11 or the gate cap layer 13 to affect performance of the semiconductor device.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

1. A semiconductor structure having buried word line, formed in a trench in a semiconductor substrate, comprising:
a gate oxide layer, formed on the inner surface of the trench;
a gate conductor, formed in the trench;
a gate cap layer, formed on the gate conductor, wherein the gate cap layer includes a first cap layer and a second cap layer, the second cap layer is disposed on the first cap layer, the first cap layer is made of TEOS oxide and the second cap layer and the first cap layer are made of different materials;
a blocking layer, disposed surrounding a bottom portion of the gate conductor, wherein the bottom portion of the gate conductor is isolated from the gate oxide layer by the blocking layer; and
an isolation structure, surrounding a top portion of the gate conductor and in contact with the top end of the blocking layer, wherein the top portion of the gate conductor is isolated from the gate oxide layer and the gate cap layer by the isolation structure.

2. The semiconductor structure according to claim 1, wherein a cross section of the isolation structure is H-shaped.

3. (canceled)

4. The semiconductor structure according to claim 1, wherein the isolation structure contains at least one material selected from the group consisting of silicon nitride and aluminum oxide.

5. The semiconductor structure according to claim 1, wherein the gate conductor contains tungsten.

6. A method of manufacturing semiconductor structure having buried word line, comprising:
providing a semiconductor substrate having a trench;
forming a gate oxide layer on the inner surface of the trench;
forming a blocking layer in the trench and at the bottom of the trench, wherein the blocking layer is disposed on the gate oxide layer;
forming a gate conductor in the trench, wherein the blocking layer surrounds a bottom portion of the gate conductor, and the bottom portion of the gate conductor is isolated from the gate oxide layer by the blocking layer;
depositing an isolation material for covering the inner surface of the trench and for covering a top portion of the gate conductor, wherein the isolation material is in contact with the top end of the blocking layer and has at least one opening;
depositing a first cap material for partially filling into the opening, wherein the first cap material is TEOS oxide;
depositing a second cap material for filling into a residual space of the opening and covering a surface of the isolation material, wherein the second cap material is a different material than the first cap material; and
removing a portion of the isolation material on the surface of the semiconductor substrate and a portion of the gate second cap material on the surface of the semiconductor substrate, for forming an isolation structure and a gate cap layer, wherein the top portion of the gate conductor is isolated from the gate oxide layer and the gate cap layer by the isolation structure.

7. The method of manufacturing semiconductor structure having buried word line according to claim 6, wherein the step of forming the gate conductor includes:
filling the trench with a gate conductor material; and
removing a portion of the gate conductor material, wherein the surface of the gate conductor material is below the surface of the semiconductor substrate.

8. The method of manufacturing semiconductor structure having buried word line according to claim 6, wherein a cross section of the isolation structure is H-shaped.

9. The method of manufacturing semiconductor structure having buried word line according to claim 6, wherein the gate cap layer includes a first cap layer and a second cap layer, and the second cap layer is disposed on the first cap layer.

10. The method of manufacturing semiconductor structure having buried word line according to claim 6, wherein the isolation structure contains at least one material selected from the group consisting of silicon nitride and aluminum oxide.
